(19) United States
(12) Patent Application Publication
(10) Pub. No.: US 2009/0308426 A1
(43) Pub. Date: Dec. 17, 2009

(54) METHOD AND APPARATUS FOR INSTALLING, TESTING, MONITORING AND ACTIVATING POWER GENERATION EQUIPMENT

(76) Inventor: KENT KERNAHAN, Cupertino, CA (US)

Correspondence Address: MICHAEL W. CALDWELL, 4226 RIVERMARK PARKWAY, SANTA CLARA, CA, 95054-4150, US

(21) Appl. No.: 12/137,085

(22) Filed: Jun. 11, 2008

(51) Int. Cl. H01L 31/042

(52) U.S. Cl. 136/244

(57) ABSTRACT

A solar panel including array converters is installed in a solar power generation system by first completing a self-test of the solar panel in an uninstalled state. Certain data is obtained and compared to specifications to verify proper operation. Other data obtained is compared to a work order to insure the intended unit is being installed. A functional, proper panel is installed into the solar power generation system, then tested again in an operational state. The system includes steps for activating a system, wherein a system that is not activated within a predetermined time period will no longer operate. The solar power generation system may be monitored remotely, thereby allowing maintenance to be performed on an as-needed basis.

### CROSS REFERENCE TO RELATED APPLICATIONS

This application is related to commonly-owned U.S. patent application Ser. No. 12/061,025 submitted Apr. 2, 2008 by Kernahan et al, which application is incorporated herein in its entirety.

### BACKGROUND

Solar powered electrical generation is rapidly being deployed industrially, commercially, and privately. With the current state of the art of construction of solar panels and the associated electronics many problems persist. A solar panel provides power anytime it is lighted which, when installing a system in bright sunlight, can create a dangerous condition. Solar panels may not be tested until a complete system is installed, thus field failures upon installation (“dead on arrival” are not unusual. Upon completion of an installation and test, there is no way to determine which of a plurality of solar panels may be faulty or out of specification. Installed panels can become mechanically unsound over time with no means for detecting the failure, thus system providers typically perform routine checks and maintenance on a calendar basis, thus sometimes wasting time on a system that is working without problems. When a system is installed, the wiring can only be checked for correct installation by visual inspection. Remote monitoring is not possible, thus a system operator cannot check on a system's performance, and theft of assets is a problem.

What is needed is a method for installing that enables a subsystem to be tested and verified as the proper unit prior to committing it to installation. It is also desirable to test a system after installation and verify operation and wiring to be correct and, if not, detect where a fault lies. Remote monitoring would reduce maintenance costs and improve reliability as well as provide for an activation requirement, thus removing the motivation for theft.

### SUMMARY

A method and apparatus are disclosed wherein a solar module, comprising a solar panel and its associated electronics, may be tested for operation and verified to be correct according to a work order prior to committing the solar module to installation. After one or more solar modules are installed, correct connections are verified and any errors reported specifically as to problem and location. An interrogation tool initiates test of a given panel, and a novel reporting tool provides an installer with verification and operational information before, during, and after installation. An activation procedure insures that the system provider is in remote contact with a system and that a system cannot be used at an unauthorized location. Provided sensors are interrogated from time to time to verify an ongoing sound condition, reporting problems when found. Sensing of operational information from time to time, providing the information to a remote operational control center, provides a method for only sending repair personnel when necessary. Sensors are also provided for detecting changes in shading of a solar panel by growing trees or new building construction.

### BRIEF DESCRIPTION OF THE DRAWINGS

FIG. 1 is a block diagram of an apparatus providing a light source for testing a solar panel.

FIG. 2 is a block diagram of a system for testing a solar panel

FIG. 3 is a top level flow chart of an example of a method for installing a power generation system.

FIG. 4-FIG. 8 are flow charts of examples of more details related to the steps according to FIG. 3.

FIG. 9 shows a solar power generation system installed on the roof of a home.

FIG. 10 is a schematic of an example of the electronics cooperatively connected to a solar panel according to the present invention.

### DETAILED DESCRIPTION OF THE INVENTION

### Definition of Some Terms

| | |
|---|---|
| Array | A power converter module for controlling an individual |
| converter | PV panel in cooperation with other similar power |
| | converter modules as disclosed in U.S. patent |
| | application 12/061,025. |
| ACPV | Array Converter Photo Voltaic module; a solar panel |
| | including an array converter incorporated therein. |
| PV | A photovoltaic panel, also sometimes referred to hereinafter |
| | as a “solar panel.” |
| Interrogation | A tool (“Interrogator”)according to the present |
| tool | invention for interrogating an ACPV to determine |
| | certain operating parameters. |
| Reporter | An ACPV test reporting tool (“Reporter”); provides |
| | information to the user in response to an interrogation tool. |

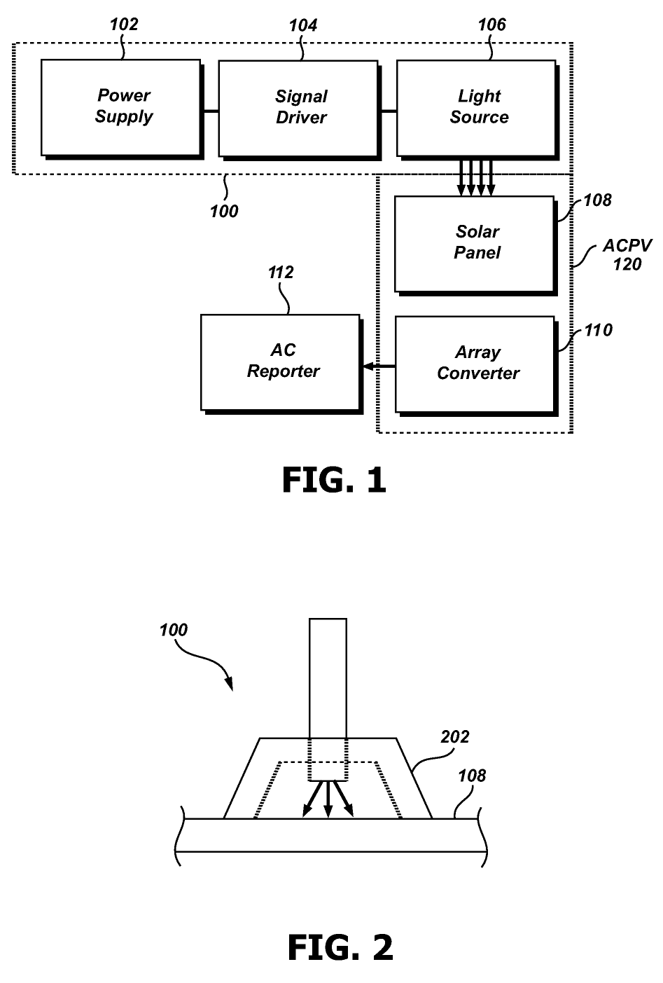

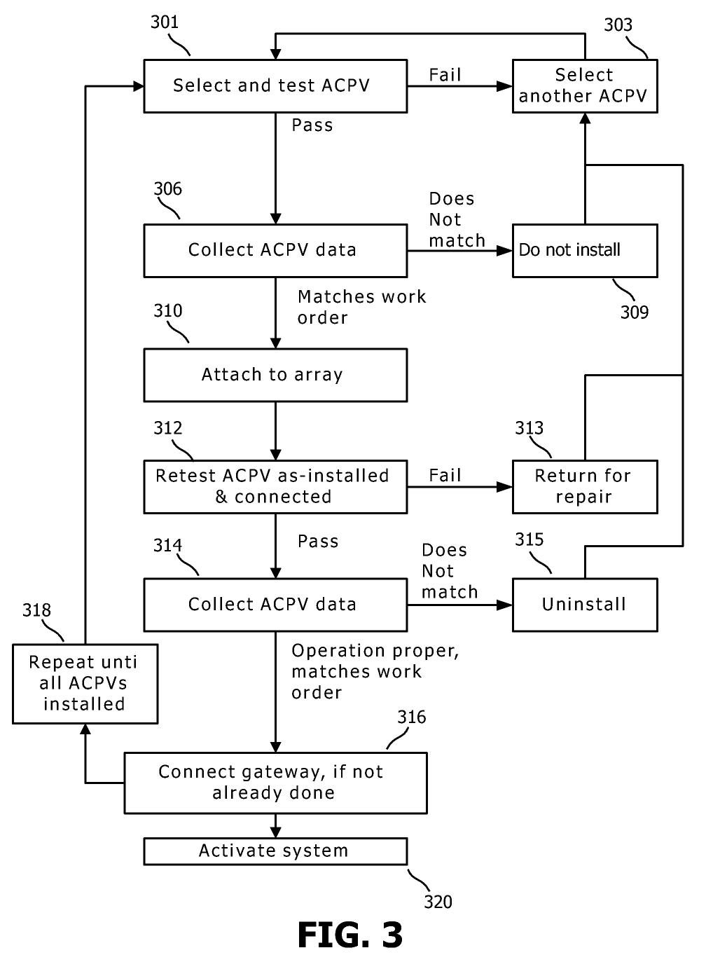

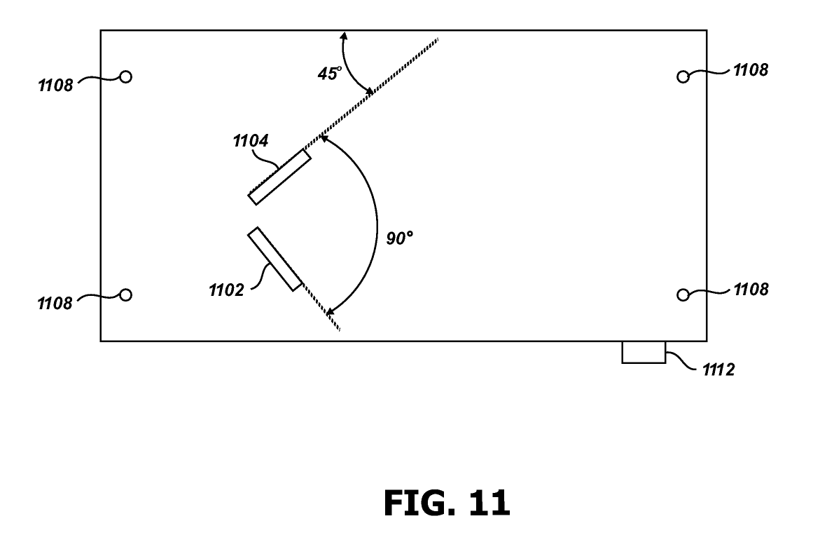

The present invention makes use of a novel testing technique and apparatus. Referring to FIG. 1, an interrogation tool (“Interrogator” 100 is disclosed. The Interrogator 100 comprises a power supply 102, a signal driver 104, and a controllable light source 106 wherein the signal driver 104 modifies the output of the power supply 102 to drive the light source 106 in a particular, meaningful pattern. The light emitted from the light source 106 is provided to an ACPV 120, wherein the ACPV 120 comprises a solar panel (PV) 108 and an array converter 110. The array converter 110 is described in greater detail in U.S. patent application Ser. No. 12/061,025. For convenience, a schematic of one embodiment of an array converter as disclosed in the aforementioned application Ser. No. 12/061,025 is presented in FIG. 10. The PV 108 is generally illuminated except for an area that will receive light emitted from the light source 106. For example, referring to FIG. 2, in one embodiment a shield 202 prevents external light from striking a portion of the surface of the PV 108 such that the light signal from the light source 106 is the only light provided to the PV 108 in the light-shielded area. The ACPV 120 will provide a relatively constant electrical output in response to the ambient incident upon the unshielded portion of the PV 108 surface. The signal from the light source 106 provides incremental electrical energy, modulating the more steady-state output of the ACPV 120. In one embodiment the Interrogator 100 is simply a flashlight, held by an installer, wherein the “power supply” 102 comprises the flashlight battery, the “signal driver” 104 is the flashlight's ON/OFF switch wherein the user turns the flashlight ON and OFF in a certain pattern, the “light source” 106 is the bulb (or LED) of the flashlight, and the flashlight is partially enclosed by a light shield 202, as shown in FIG. 2. In some circumstances, for example if an ACPV 120 is in less than full ambient sunlight, the Interrogator 100 source 106 may be able to provide enough incremental electrical energy such that the shield 202 is not necessary. The essence of the Interrogator 100 is that a light source 106 provides a signal pattern of light energy to an array converter 110 such that the incremental electrical energy generated by the array converter rides upon the relatively steady-state output of the ACPV 120. The array converter demodulates the signal pattern provided by the Interrogator 100 and interprets the signal pattern. In some embodiments the Interrogator 100 includes means for indicating that the Interrogator 100 is working properly or improperly (not shown), including an error code. The indication means include such examples as a beeper, vibrator, light, radio wave or an LED. The array converter 110 may provide responsive information to a Reporter 112. In one embodiment a controller 1002 incorporated in the array converter, as shown in FIG. 10, provides a signal on a line 1006 to the control gate of a transistor 1006. The transistor 1006 is across the PV 108 output. A solar panel is a constant current device (for a given light level), thus shorting the output across the solar panel by the transistor 1006 causes the output voltage (at terminals P1 and P2) to collapse. Thus by modulating the signal to the control gate of the transistor 1006 a powerful signal may be created by the output of the array converter 100. In one embodiment the output is provided to the PV 108, thereby creating a near field signal. In one embodiment the near field signal is modulated to a standard amplitude modulated radio frequency (“a.m. radio”), for example 560 KHz, and the Reporter 112 includes an a.m. radio receiver for receiving information from the array converter 110.

In another exemplary embodiment the power supply 102 is a battery pack, the signal driver 104 comprises drivers capable of modulating the power provided to the light source 106 and a microcontroller wherein the microcontroller has been preprogrammed with predetermined signal symbols, and the Reporter 112 has been preprogrammed to interpret the signal symbols received from the array converter 110 and respond with certain data. For example, in one embodiment the signal provided by the signal driver 104 is a sequence of manchester-encoded symbols. The manchester-encoded symbols are provided by the array converter 110 to the Reporter 112 for interpretation. For systems wherein each and every PV 108 is not accessible, the Interrogator 100 may be affixed to a pole, thereby allowing an installer to place the interrogator (and optional shroud 202) in close proximity to all PV 108 panels.

Looking still to FIG. 1, the Reporter 112 may be coupled to the AC converter 110 by a variety of means, such as an RF signal, a modulated IRLED beam, a modulated laser beam, or a removable wire. In one embodiment the AC converter 110 drives the PV 108 with a high frequency signal, for example 560 KHz, thereby creating a near-field RF signal. The Reporter 112 includes a receiver for detecting such an RF frequency. The Reporter 112 is positioned near the surface of the PV 108, thus a near-field transmitter/receiver cooperative system is created. The data provided by the AC converter 110 to the Reporter 112 can be any of a variety of forms. For example, in some embodiments the near-field signal provides a serial data stream, wherein the symbols are in the form of time-domain modulation, pulse-position modulation, or manchester-encoding. In another exemplary embodiment the near-field RF transmission is amplitude modulated with predetermined voice messages. One of ordinary skill will know of many alternative methods for transmitting data using near-field RF.

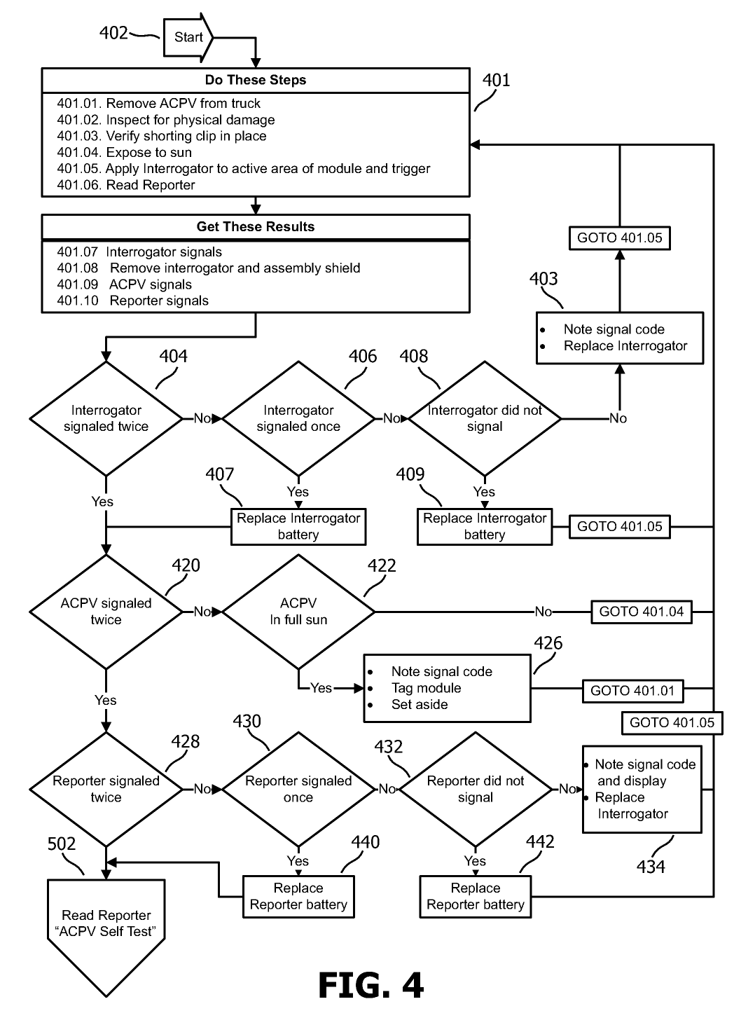

Referring to FIG. 3, an ACPV 120 is selected for installation and testing 301 using an Interrogator 100 and an Reporter 112. If the ACPV 120 fails the test, a different ACPV 120 is selected 303 for installation and test 301. If the ACPV 120 passes the test, an Reporter 112 (coupled with the ACPV 120 as described hereinbefore) is observed to verify certain predetermined data relative to the ACPV 120. The information provided by the Reporter 112 is compared to the installation data, such as a work order provided to an installer. If the information does not match the installation data the instant ACPV 120 is not installed 309, a different ACPV 120 is selected 303 for installation and test 301. If the information reported by the Reporter 112 for the instant ACPV 120 matches the work order, the ACPV 120 is attached to an array of compatible ACPVs 120 comprising the power generation elements of a power generation system according to the invention disclosed in aforementioned U.S. patent application Ser. No. 12/061,025.

With the ACPV 120 installed into the power generation system being assembled, the ACPV 120 is again tested 312 using the Interrogator 100 and Reporter 112. If the ACPV 120 now fails the test the ACPV 120 is returned for repair 313, a different ACPV 120 is selected 303 for installation and test 301. If at step 312 the ACPV 120 is deemed operational the data now reported by the Reporter 112 is observed for additional data and compared to the work order 314. If the data does not match the work order the ACPV 120 is uninstalled 315, a different ACPV 120 is selected 303 for installation and test 301. If the ACPV 120 passes the test 314, a gateway is connected to the system 316, if not done previously. The process described hereinbefore is repeated from step 301 to step 316 until all ACPVs 120 that are required for the system are in place 318. Following complete installation the system is activated 320 and installation is complete.

The above description discloses in general terms the overall process of installing a system in accordance with the disclosure of U.S. patent application Ser. No. 12/061,025 using the method and apparatus of the present invention. The process of FIG. 3 and the above description is a specific example of an installation process. Variations in sequence and details are encompassed by the present invention.

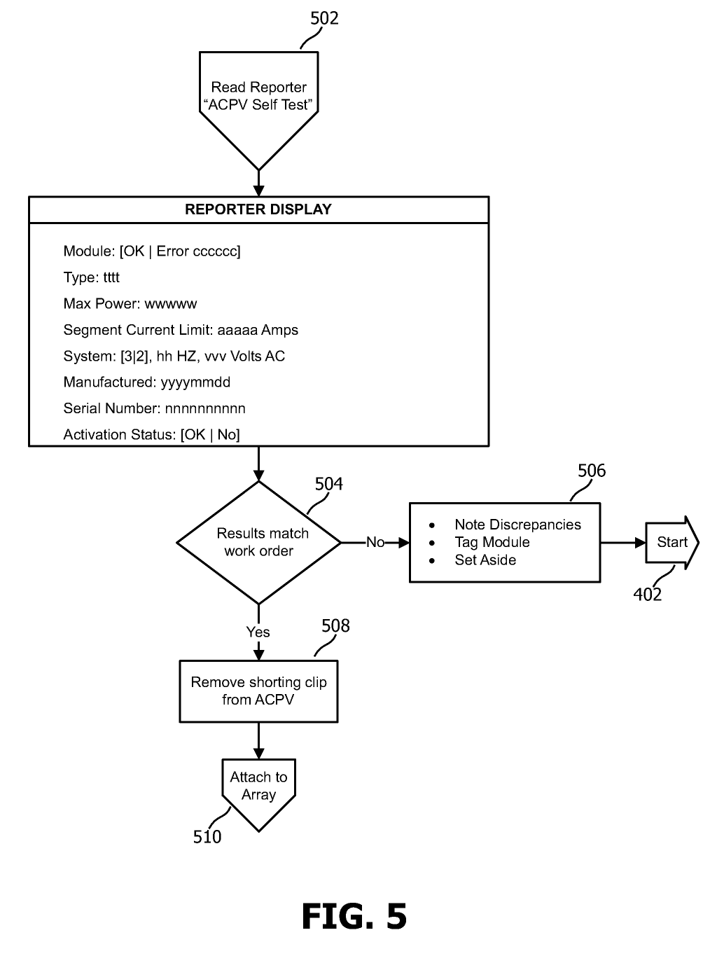

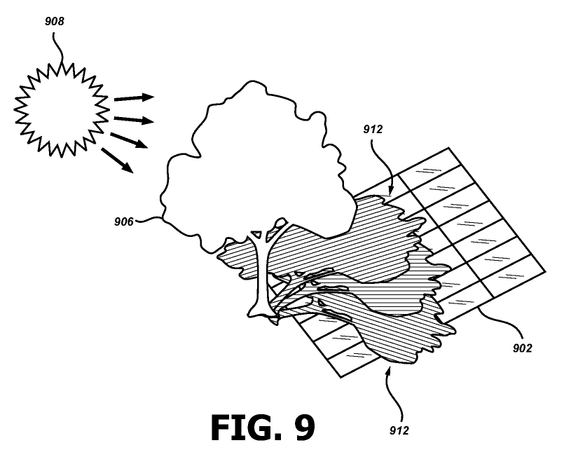

Beginning with FIG. 4 and continuing through FIG. 8, a more detailed treatment of the steps of FIG. 3 is presented. Looking to FIG. 4, an entry point “Start” 402 is defined. Other figures may have exit steps that return to Start 402. Following Start 402, an ACPV 120 module is selected by an installer for installation at step 401. Step 401 comprises several smaller steps, annotated as “401.n”, wherein the steps “n” are shown in FIG. 4. Later steps may indicated returning to a step within step 401 by using this annotation. For example, a path in the flow chart may indicate to return to “step 401.05”, which indicates applying an Interrogator 100 to an active area of an ACPV 120 module and triggering the Interrogator 100.

At step 401.01 an installer removes an ACPV 120 from the delivery vehicle and inspects the ACPV 120 for physical damage 401.02. For safety, a shorting clip is in place or is put in place 401.03 to short the output terminals of the instant ACPV 120. However note that an ACPV 120 is designed such that it will not provide output power unless the ACPV 120 has been enabled to do so, thus the shorting clip is an extra safety step in case of a failure of the array converter 110. In normal operation, the shorting clip enables the PV 108 to provide current, thus enabling testing of the ACPV 120. The ACPV 120 is exposed to a light source 401.04, for example sunlight, and an Interrogator 100 is applied to an active area of the ACPV 120 and triggered 401.05. The Reporter 112 is then read 401.06 for the results of the interrogation.

After the Interrogator 100 is triggered 401.05 the Interrogator 100 responds 401.07, for example with a number of beeps. The Interrogator 100 is removed 401.08. The ACPV 120 should provide a signal 401.09, such as a click or beep or light flash or radio signal, provided by the controller 1002 of the ACPV 120. The Reporter 112 then provides a signal 401.10, such as a beep.

Step 404 verifies that the Interrogator 100 provided a signal a predetermined number of times, for example two. If so, the Interrogator 100 is known to have been operating properly and to have reported that the ACPV 120 responded properly, and step 420 is taken. If the Interrogator 100 did not respond as expected at step 404, step 406 checks to see if the Interrogator 100 provided a predetermined error signal, for example one beep. If the predetermined signal was observed at step 406, the predetermined signal indicates that the ACPV 120 responded correctly but that the voltage of the power supply 102 of the Interrogator 100 is low. If the predetermined signal is observed at step 406 the power supply 102 of the Interrogator 100 is replaced 407 and the process proceeds to step 420. If the Interrogator 100 did not respond with the predetermined signal at step 406 the installer checks for any signal at all 408. The responses to be observed at step 408 are predetermined by the design of the Interrogator 100. In the example shown, no signal at all indicates power supply failure, and the power supply is replaced 409 then the process returns to step 401.05 because the status of the instant ACPV 120 is not known. In some embodiments other failure modes of the Interrogator 100 are predetermined and indicated by a predetermined number of signals from the Interrogator 100. In such a case the number of signals, sometimes called a “beep code,” is noted by the installer for later repair of the Interrogator 100 and the Interrogator 100 is replaced 403 by another Interrogator 100 and the process returns to step 401.05.

Step 420 tests for a predetermined signal from the ACPV 120 module itself. In one example, the ACPV 120 energizes a relay incorporated into the ACPV 120, providing an audible click that an installer can hear. In other embodiments, a beeper or other source of noise provides the signal. Of course a light, such as an LED or small incandescent bulb, is suitable for providing a visual signal. Regardless of the signaling means, step 420 checks that the ACPV 120 indicated proper operation. If the predetermined signal is not observed step 422 checks that the ACPV 120 was exposed to full sun during the test. If not, the panel is exposed to full sunlight as in step 401.04, and the process repeats from step 401.04. If the panel was exposed to full sunlight (and the predetermined signal was not observed at step 420) we assume the ACPV 120 is flawed and go to step 426. At step 426 any signal code is noted, the ACPV 120 module tagged for later troubleshooting and set aside. Next the entire process is repeated from step 401.01.

If the expected signal was observed at step 420 we go next to step 428 and observe the Reporter 112 for a predetermined signal, for example signaling twice. If the expected signal is not observed the Reporter 112 is observed for another signal, for example one beep. One signal is predetermined to indicate that the Reporter 112 properly received data from the ACPV 120 but that the Reporter 112 battery is low. The battery is replaced 440 in the Reporter 112 and the process continues to step 438.

If the expected (single) signal was not observed at step 30 step 432 checks to see if any signal at all was observed from the Reporter 112. If no signal, the battery in the Reporter 112 is replaced 442 and the process begins again at step 401.05. Similar to the test of the interrogator at step 403, step 434 notes any beep code received from the Reporter 112, replaces the Reporter 112, and returns to step 401.05.

If the expected signals (for example, two) were observed at step 428 a display on the Reporter 112 is read. Note that the ACPV module test at step 420 is very simple self test. At step 502 the Reporter 112 provides detailed information regarding the ACPV 120. Example data is whether the module is good, else an error code; the type of module, for comparison with a work order; the maximum power rating; the current limit; the voltage and frequency design specifications; date of manufacture; serial number; and activation status. Less than all of these data may be reported, or other data as may be of interest to an installer or manufacturer.

Step 504 verifies that the data reported by the Reporter 112 matches the work order. If the data does not match the work order the discrepancies are noted, the ACPV 120 tagged for identification and set aside 506 and the process started all over again 402 with a different ACPV 120. If the data observed at step 504 matches the work order the shorting clip is removed from the ACPV 120 output terminals 508 and the ACPV 120 is attached 510 into the power system.

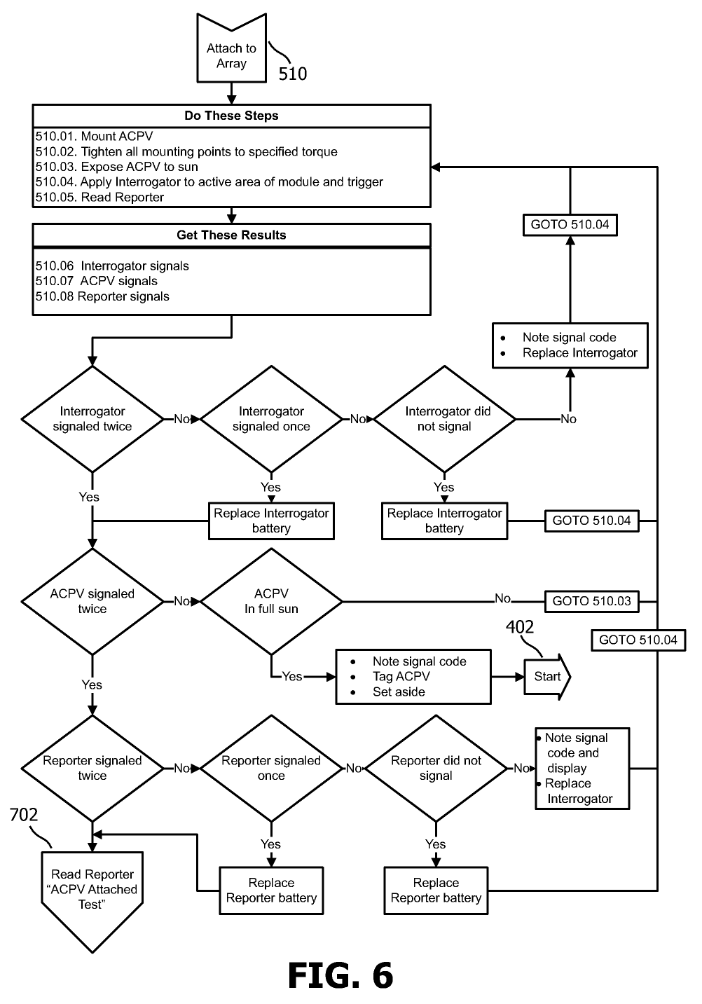

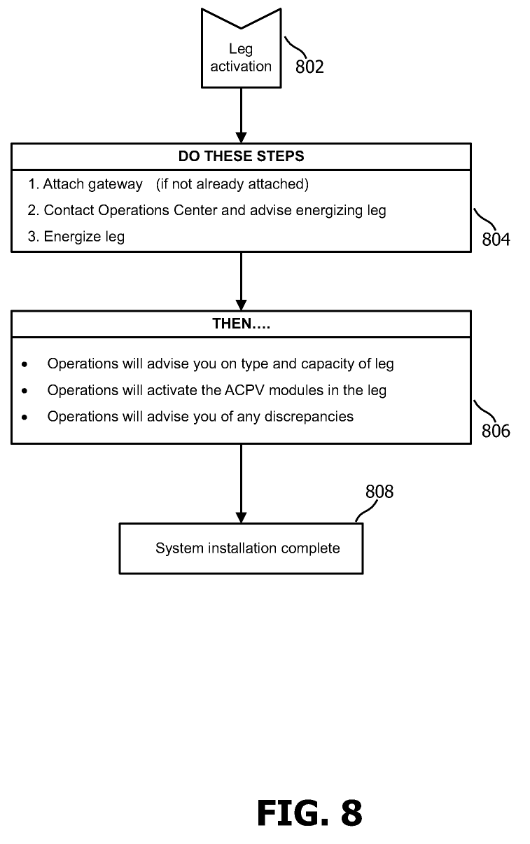

The test flow from step 510 through step 702 is essentially the same process as that hereinbefore described for steps 401 through 502 (FIG. 4) and is not repeated here. ACPV 120 is tested without being installed per the flow described by FIG. 4, then retested per the flow described by FIG. 5 after the ACPV 120 is installed into the power system. Note, though, that step 501 includes the steps of mounting 501.01 the ACPV 120 and tightening the ACPV 120 mechanical mounting points to a torque specification. As with step 502, step 702 includes observing the Reporter 112 for data relative to the operation of the ACPV 120, now within the environment of a power generation system. Note that the interrogation of an ACPV 120, and the resulting collection of data, may be done at times other than during installation of a system, for example as routine maintenance or monitoring. The Interrogator 100 is generally anticipated to be a portable, hand-held device whose purpose is to stimulate the ACPV 120 to provide certain data to the Reporter 112, thus convenient at the time of installation. Once one or more ACPV 120 modules are installed in a power generation system and the system is connected to the internet via a gateway (as described in more detail in aforementioned U.S. patent application Ser. No. 12/061,025), the ACPV 120 can be remotely commanded to report the same data as in FIG. 7 step 702. The report may be made to a Reporter 112 as hereinbefore described, with an installer observing the Reporter 112, or the data may be transmitted back to a remote station using the internet connection. In some embodiments step 702 includes additional data compared to that reported at step 502. Examples of the additional data relative to an ACPV 120 include a determination that the ACPV 120 is dirty; whether the ACPV 120 has been cracked, including a time stamp; whether the ACPV 120 suffered an impact, including a time stamp; a value of degradation of the performance of the ACPV 120 compared to the as-installed performance; the status of the attachment bolts of the frame of the ACPV 120, such as whether the frame is twisted or a bolt is lose or missing; the front and back temperatures of the ACPV 120, perhaps with time stamps; status of the grid to which the power generation system is connected; a configuration symbol; the lifetime yield of the ACPV 120; the days in service of the ACPV 120; yield of the ACPV 120 since the last interrogation; and the number of days since the last interrogation of the ACPV 120. Clearly less than all of these example data types is within the scope of the present invention, and likewise one skilled in the art will know of other data that would be of value to the owner or user of the power generation system.

At the time of installation an ACPV 120 is mechanically affixed to a structure holding the power generation system, the structure typically located on a roof or in an open field. Due to a harsh environment of temperature, wind, rain, snow, hail, and other environmental factors it is usual to secure solar panels very securely, for example by tightening down nuts and bolts to a predetermined torque. In one embodiment of the present invention the torque is remotely monitored, enabling a system operator to detect that a bolt has become lose (or dislodged altogether). At the time of installation the bolts are tightened to a predetermined torque. Looking to FIG. 11, a PV 108 of the ACPV 120 is provided with four rigid protrusions (collectively numbered 1108) wherein the protrusions 1108 make contact with the substrate to which the PV 108 is secured. The mounting bolts for the ACPV 120 (not shown) are outside the circumscribed perimeter of the rigid protrusions 1108, such that as the bolts are torque the PV 108 has some amount of bending. It is usual for PV 108 manufacturers to specify the torque value for the bolts. Still looking to FIG. 11, a strain gauge 1102 and a strain gauge 1104 is affixed to a surface of the PV 108. The two strain gauges 1102, 1104 are placed such that their longitudinal axes are ninety degrees apart. The strain gauges 1102, 1104 are also placed such that their longitudinal axes are forty five degrees relative to a frame (not shown) of the PV 108. At step 510.02 the bolts are tightened to a predetermined torque value and the readings of the strain gauges 1102, 1104 recorded. At step 702 the strain gauge 1102, 1104 readings are compared to predetermined values to insure that the bolts were properly torque initially, which will also verify that a PV 108 panel is not improperly twisted. A system operator may from time to time interrogate an ACPV 120 and evaluate the new strain gauge 1102, 1104 readings. For example, analysis of the data can determine if a bolt has come off completely or if a bolt or bolts are becoming lose. The analysis may also indicate that the PV 108 is twisted.

Looking to FIG. 7, the Reporter 112 is observed for certain predetermined data 702 and the data so observed compared to the requirements of an installation work order and to the specifications of the ACPV 120 to determine that the ACPV 120 is working properly 704. If there are discrepancies they are corrected by the installer 706 if possible then the process returns to step 510.04 to reinstall and test the ACPV 120. If the status of the ACPV 120 is good and the data 702 matches the work order 704 we check to see if all ACPV 120 modules for the instant power generation system have been installed 708. If there are more ACPV 120 modules to be installed the process begins again 402, else continues to activate the instant leg 802.

In another embodiment a device 1112 is affixed to the PV 108, wherein the device 1112 provides a mechanical pulse, similar to a click or a tap, to the PV 108. The device 1112 may be affixed at any of a variety of locations, such as the top or bottom surface of the PV 108, on one edge or side of the PV 108 frame, and such. The device includes means to activate it to mechanically excite the ACPV 120 (not shown) and a microphone (not shown) receives the returning sound data responsive to the mechanical tap from the device 1112. Many techniques are known in the art for analyzing the returning audible signal to determine that a crack may have developed in the structure. In some embodiments the microphone constantly “listens” for a sound pattern known to indicate a glass breaking, such as from hail or a thrown rock.

In some embodiments a remote operations center has overall control of a power system. For example, a system may be allowed to connect to a grid and produce power (be “energized” for a limited time and, if not activated by the remote operations center by a certain time, for example ten days, then the system stops producing power. Leg activation 802 begins with the steps of attaching a gateway (if not already done), contacting an operations center to inform the center the leg is being energized by the installer, and then causing the leg to be energized 804. With the leg energized the leg is fully functional, but is not yet activated by the operations center. In one embodiment the operations center examines data received from the power generation system, comprised of a plurality of ACPVs 120 cooperatively connected in accordance with the aforementioned U.S. patent application Ser. No. 12/061,025 wherein the controller for the system or the Reporter 112 (if so connected) provides certain data back to the operations center, the data similar to that disclosed in association with step 702. The operations center may advise the installer what type and capacity the leg represents as a cross check. The operations center activates the ACPV 120 modules and advises of any discrepancies 806. Assuming all results are as expected, installation is now complete 808.

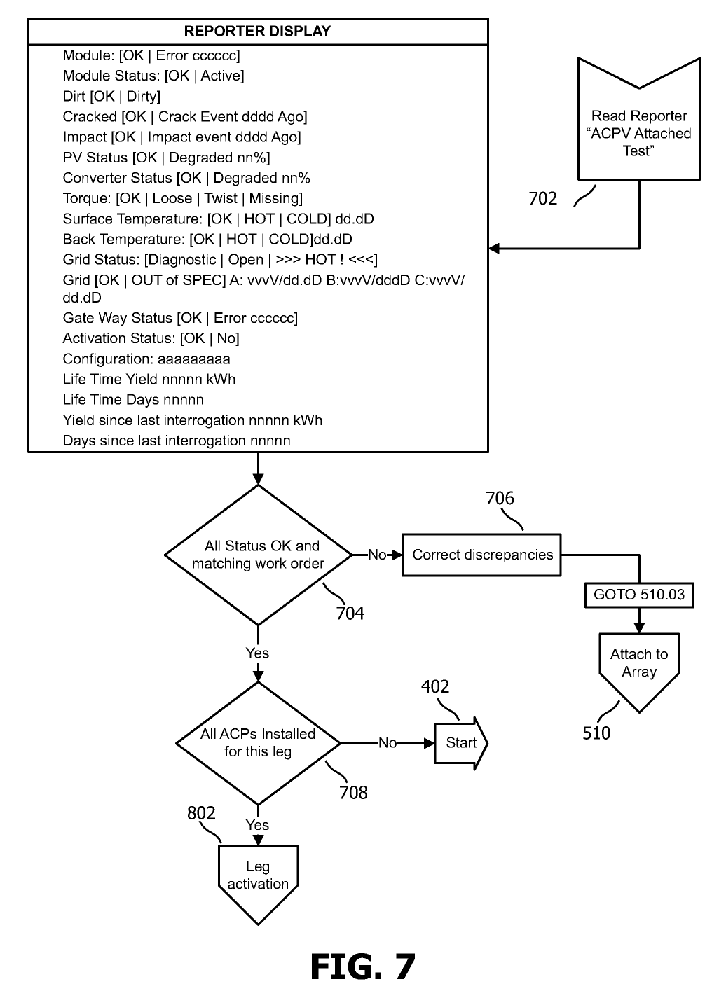

The descriptions related to FIG. 3 through FIG. 8 are exemplary of a specific embodiment of the present invention for an installation and test verification process. More or fewer steps with variations in details of numbers and sequence are within the scope of the present invention and are claimed by the applicant.

A power generation system designed in accordance with the aforementioned U.S. patent application Ser. No. 12/061,025 and installed in accordance with the present invention provides for other novel uses such as monitoring a system periodically. Such monitoring is useful by providing a means for repair actions to be taken upon detected need rather than by a routine schedule. Since the experience of reliability, damage, and environment over time will vary from installation to installation, time-based maintenance must be scheduled anticipating the worst-case scenario, thereby wasting money on systems with a better experience. For example, an operations center may periodically request data from a power generation system wherein the data requested is similar to that disclosed in association with step 702 and record the response in a database. Trend data of such specific data as surface or back temperatures may indicate a problem with a system or a change in the surrounding environment that warrants a maintenance investigation. Slow changes in torque readings may indicate that an ACPV 120 is becoming lose in its attachment to the system and the bolts need attention. An indication of one or more ACPV 120 modules being dirty might indicate to the operations center that the system owner should be notified to clean the ACPV 120 or perhaps sending someone to clean the panel if a maintenance contract covered that action. Detection of a cracked panel would enable timely repair.

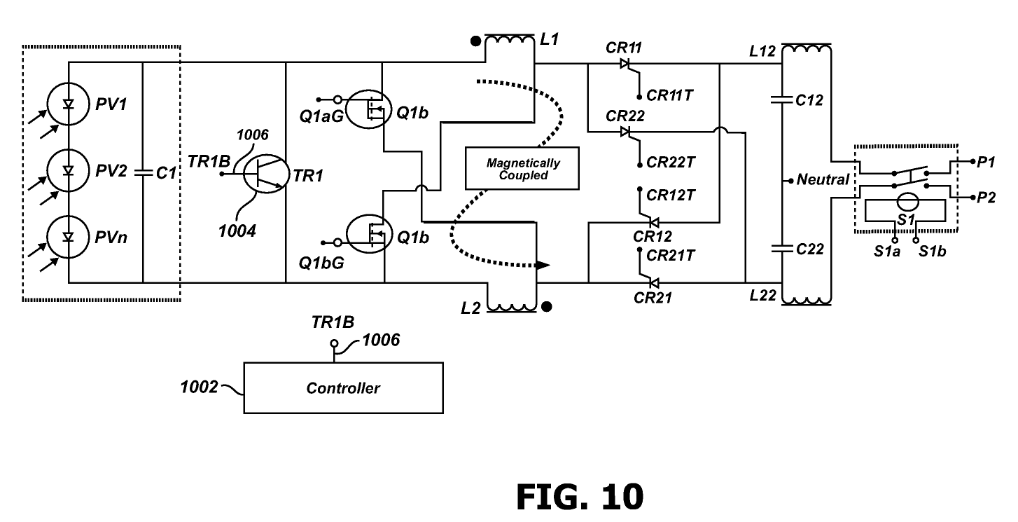

The efficiency and total power delivered by a solar powered system obviously depends upon the degree to which a system is able to receive full sunlight. The sunlight available may change over time due to buildings being built next to an installed system or nearby trees growing taller. In one embodiment of the present invention an installer records the physical location of each ACPV 120 module as-installed relative to the earth (longitude and latitude) as well as relative to an identified certain location on the premises wherein the system is installed. Looking to FIG. 9, an installed solar power generation system 902 is installed on the roof of a house 904 wherein the location and orientation of the house and each ACPV 120 module within the system 902 are known to and recorded by the operations center, the information being provided by an installer. A nearby tree 906 sometimes shades all or less than all of the ACPVs 120 during certain times of the day and/or time of the year. By knowing the position and orientation of the ACPVs 120 and observing and recording the power data available from each ACPV 120 one may determine the position and height of the tree (or other obstacle blocking the sun 908) using simple geometry and time of day plus day of the year information. In some municipalities it is becoming a requirement for one neighbor to prevent his landscaping, such as a tree, or home addition from blocking another neighbor's solar power system. As the tree 906 grows and perhaps shades more and more of the solar power system 902 the data will provide evidence of the tree's 906 effect on efficiency and the facts of its height and location.

### RESOLUTION OF CONFLICTS

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

What is claimed is:

1. An apparatus for providing a signal to a solar panel controller, wherein the solar panel controller includes means for detecting an electrical signal superimposed upon a power signal provided by a solar panel responsive to ambient light, comprising:
a power supply connected to a signal driver, the signal driver further connected to a light source wherein the signal driver modifies the light output of the light source by modifying the power provided to the light source by the power supply when the light source is directed to an active area of a solar panel surface.

2. The apparatus according to claim 1, further including a light shield wherein the light shield surrounds the light source, thereby preventing ambient light from striking the solar panel in an area that receives light from the light source.

3. A method of installing solar power producing modules comprising the steps of:
a. selecting a solar panel for installation;
b. testing the solar panel in isolation from other solar panels;
c. attaching the solar panel to a structure for supporting a solar power generating system;
d. electrically connecting the solar panel to the solar power generating system;
e. retesting the solar panel in an operative mode within the environment of the solar power generating system;
f. repeating steps 3a through 3e until all required solar panels are installed in a solar power generation system; then
g. activating the solar power generation system.
